(19) United States
(12) Patent Application Publication
(10) Pub. No.: US 2021/0032276 A1
(43) Pub. Date: Feb. 4, 2021

(54) NEAR-INFRARED ABSORBING COMPOSITION, NEAR-INFRARED ABSORBING FILM AND IMAGE SENSOR FOR SOLID-STATE IMAGING ELEMENTS

(71) Applicant: Konica Minolta, Inc., Tokyo (JP)

(72) Inventors: Natsumi ITAMOTO, Hino-shi, Tokyo (JP); Koji DAIFUKU, Hino-shi, Tokyo (JP); Yosuke MIZUTANI, Mitaka-shi, Tokyo (JP); Keigo TAMAKI, Fukuroi-shi, Shizuoka (JP); Yutaro HORIE, Hachioji-shi, Tokyo (JP); Kenji HAYASHI, Hino-shi, Tokyo (JP); Issei NAKAHARA, Hino-shi, Tokyo (JP); Takahiko NOJIMA, Setagaya-ku, Tokyo (JP); Kiyoshi FUKUSAKA, Fussa-shi, Tokyo (JP)

(21) Appl. No.: 17/042,539

(22) PCT Filed: May 29, 2019
(86) PCT No.: PCT/JP2019/021317

§ 371 Date: Sep. 28, 2020

(30) Foreign Application Priority Data
Jun. 19, 2018 (JP) 2018-115679

(51) Int. Cl. C07F 9/09; H01L 27/146; G02B 5/22

(52) U.S. Cl. CPC C07F 9/093; H01L 27/1462; C07F 9/097; C07F 9/091; G02B 5/223

(57) ABSTRACT

Provided is a near-infrared ray absorbing composition including a near-infrared absorber and a solvent, wherein the near-infrared absorber contains at least one of the following component (A) and component (B); and a compound represented by Formula (I) is contained in the component (A) or component (B) in the range of 0.001 to 10% by mass based on the total mass of the near-infrared ray absorbing composition, Component (A): a component composed of at least one of a compound represented by Formula (1) or Formula (2) with a compound represented by Formula (I) and a copper ion, Component (B): a component composed of a copper complex obtained by reaction of at least one of a compound represented by Formula (1) or Formula (2) with a compound represented by Formula (I) and a copper compound,

O═P—(OH)₃ Formula (I):

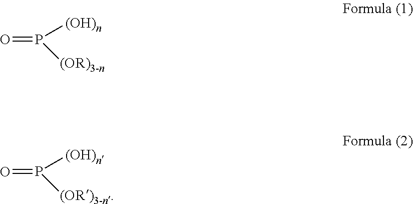

### TECHNICAL FIELD

The present invention relates to a near-infrared ray absorbing composition, a near-infrared ray absorbing film using the same, and an image sensor for a solid-state imaging device. More specifically, the present invention relates to a near-infrared ray absorbing composition having high dispersibility and high transmittance in the visible region, and having excellent absorption characteristics in the near-infrared region, a near-infrared ray absorbing film using the same, and an image sensor for a solid-state imaging device equipped with the near-infrared ray absorbing film.

### BACKGROUND

CCD (Charge Coupled Device) and CMOS (Complementary Metal Oxide Semiconductor) image sensors, which are solid-state imaging devices for color images, have been used in video cameras, digital still cameras, and mobile phones with camera functions. These solid-state imaging devices use a silicon photodiode having sensitivity to light in the near-infrared wavelength region in the light receiving part, therefore it is necessary to perform luminosity correction. For that reason, a near-infrared ray cut filter is often used.

On the other hand, as a photometric filter of an imaging camera or an optical filter for correcting luminosity of an imaging system such as a video camera, an optical filter made of glass in which copper ions are contained in a special phosphoric acid glass is used.

However, in addition to being heavy and having high hygroscopicity, this type of glass optical filter has problems such as difficulty in processing operations such as a molding process, a cutting process, and a polishing process in the manufacture of the optical filter.

As an optical filter for solving the above problems, an optical filter containing an ionic metal component having a phosphoric acid ester compound having a specific structure and a copper salt as a main component, efficiently cuts light in the near infrared region. This optical filter is made of a synthetic resin that is lightweight, and it has low hygroscopicity, and is easily processed (for example, refer to Patent Document 1).

Further, there has been disclosed an optical filter which contains a phosphoric acid ester copper compound obtained by reaction of a phosphoric acid ester compound having a specific structure and a copper ion or a copper compound, and which is provided with a near-infrared light absorbing layer containing a content of copper ions relative to a phosphorus atom in a range of a specific ratio, and which is excellent in sufficient near-infrared light absorbing property and moisture resistance (for example, refer to Patent Document 2).

However, in the optical filter using these proposed phosphate ester compounds and phosphate ester copper compounds containing copper ions as a main component, the absorption coefficient is not high, and further, the absorption performance in the wavelength range of 900 to 1100 nm required for the filter for correcting the luminous sensitivity of the imaging system is found to be insufficient, and immediate improvement is required.

### PRIOR ART DOCUMENTS

### Patent Documents

Patent Document 1: JP-A 6-118228

Patent Document 2: JP-A 2001-154015

### SUMMARY OF THE INVENTION

### Problems to be Solved by the Invention

The present invention has been made in view of the above-mentioned problems and situation. An object of the present invention is to provide a near-infrared ray absorbing composition having high dispersibility and transmittance in the visible region and excellent absorption characteristics in the near-infrared region. An object of the present invention is also to provide a near-infrared ray absorbing film formed using the same, and an image sensor for a solid-state imaging device including the near-infrared ray absorbing film.

### Means to Solve the Problems

The present inventor has found the following as a result of studying the cause of the above problems in order to solve the above problems. That is, by using a near-infrared ray absorbing composition containing a near-infrared absorber and a solvent, wherein the near-infrared absorber contains: a copper complex obtained by reaction of a phosphoric acid ester compound having a specific structure, and a copper ion or a copper compound; and a phosphoric acid which is a compound having a structure represented by the following Formula (I) contained in a specific range, it is possible to achieve a near-infrared ray absorbing composition having high dispersibility, high transmittance in the visible region, and excellent absorption characteristics in the near-infrared region. It is also possible to achieve a near-infrared ray absorbing film formed using the same, and an image sensor for a solid-state imaging device including the near-infrared ray absorbing film. As a result, the present invention has been achieved.

In other words, the above problem according to the present invention is solved by the following means.

1. A near-infrared ray absorbing composition comprising a near-infrared absorber and a solvent, wherein the near-infrared absorber contains at least one of the following component (A) and component (B); and a compound having a structure represented by Formula (I) is contained in the component (A) or component (B) in the range of 0.001 to 10% by mass based on the total mass of the near-infrared ray absorbing composition.

Component (A): a component composed of at least one of a compound having a structure represented by Formula (1) or Formula (2) with a compound having a structure represented by Formula (I) and a copper ion

Component (B): a component composed of a copper complex obtained by reaction of at least one of a compound having a structure represented by Formula (1) or Formula (2) with a compound having a structure represented by Formula (I) and a copper compound,

O═P—(OH)₃ Formula (I):

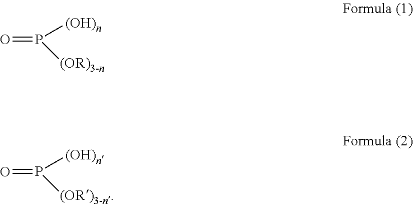

In the above Formula (1), R represents at least one group selected from the Formulas (A) to (H) and (J); n represents 1 or 2, and when n represents 1, a plurality of R may be the same or different.

In the above Formula (2), R′ represents an alkyl group, an aryl group, an aralkyl group, or an alkenyl group each having 1 to 18 carbon atoms, and the total carbon atom number is in the range of 1 to 36; n′ represents 1 or 2, and when n′ represents 1, a plurality of R′ may be the same or different.

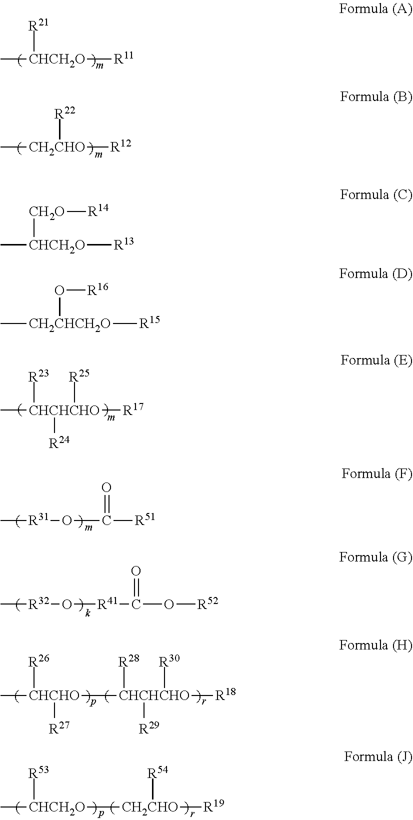

In the above Formulas (A) to (H) and (J), R¹¹ to R¹⁹ each respectively represent an alkyl group having 1 to 20 carbon atoms, an aryl group having 6 to 20 carbon atoms, or an aralkyl group having 6 to 20 carbon atoms (provided that at least one hydrogen atom bonded to a carbon atom constituting an aromatic ring may be substituted with an alkyl group having 1 to 6 carbon atoms, or a halogen); R²¹ to R³⁰ each respectively represent a hydrogen atom or an alkyl group having 1 to 4 carbon atoms; R³¹ and R³² each respectively represent an alkylene group having 1 to 6 carbon atoms; R⁴¹ represents an alkylene group having 1 to 10 carbon atoms; R⁵¹ and R⁵² each respectively represent an alkylene group having 1 to 20 carbon atoms; and R⁵³ and R⁵⁴ each respectively represent a hydrogen atom or an alkyl group having 1 to 4 carbon atoms, provided that one of R⁵³ and R⁵⁴ is always a hydrogen atom, and both of R⁵³ and R⁵⁴ are not a hydrogen atom at the same time; m represents an integer of 1 to 12, k represents an integer of 0 to 5, p represents an integer of 1 to 10, and r represents an integer of 1 to 10.

2. The near-infrared ray absorbing composition according to item 1, wherein a solid content concentration is in the range of 5 to 50% by mass.
3. The near-infrared ray absorbing composition according to item 1 or 2, wherein an average transmittance in a wavelength range of 450 to 550 nm is 70% or more when a transmittance at a wavelength of 850 nm is made to 1.0%.
4. The near-infrared ray absorbing composition according to any one of items 1 to 3, containing a near-infrared absorption modifier having an absorption maximum wavelength in a wavelength range of 650 to 1000 nm.
5. A near-infrared ray absorbing film formed with the near-infrared ray absorbing composition according to any one of items 1 to 4 is used.
6. An image sensor for a solid-state imaging device comprising the near-infrared ray absorbing film according to item 5.

### Effects of the Invention

According to the above-mentioned means of the present invention, it is possible to provide a near-infrared ray absorbing composition having high dispersibility and transmittance in the visible region and excellent absorption characteristics in the near-infrared region. It is also possible to provide a near-infrared ray absorbing film formed using the same, and an image sensor for a solid-state imaging device including the near-infrared ray absorbing film.

The expression mechanism and action mechanism of the effect of the present invention are not clarified, but are inferred as follows.

The near-infrared ray absorbing composition of the present invention is a near-infrared ray absorbing composition containing a near-infrared absorber and a solvent, wherein the near-infrared absorber contains at least one of the component (A) and the component (B), and a compound having a structure represented by Formula (I) is contained in the component (A) or the component (B) in the range of 0.001 to 10% by mass based on the total mass of the near-infrared ray absorbing composition.

In the conventional near-infrared ray absorbing composition which contains a component composed of at least one of compounds having a structure represented by Formula (1) or Formula (2) and a copper ion, or a component composed of a copper complex obtained by the reaction of at least one of the compounds having a structure represented by Formula (1) or Formula (2) with a copper compound, it is true that the near-infrared ray absorbing composition was excellent in dispersion stability and near-infrared ray cutting stability of the constituent materials. Further improvements have been demanded for the absorption performance in a higher infrared region, which has been required in recent years.

As a result of extensive studies on the above problems, the present inventor has conducted extensive studies on the above problems, it has been possible to obtain the following near-infrared ray absorbing composition. This near-infrared ray absorbing composition is composed of a copper complex obtained by reaction of a phosphoric ester compound with a copper ion or a copper compound, and further, by containing phosphoric acid, which is a compound having a structure represented by Formula (I), in the range of 0.001 to 10% by mass of the total mass of the near-infrared ray absorbing composition, it is possible to convert an absorption wavelength with high accuracy by a heat treatment, and in particular, to improve an absorption performance in a wavelength range of 900 to 1100 nm.

It is presumed to achieve the effect by the following reason. By the near-infrared ray absorbing composition containing a copper complex obtained by reaction of a phosphoric ester compound with a copper ion or a copper compound, and further containing phosphoric acid which is a compound having a structure represented by Formula (I), the electronic state around the copper ion coexisted is changed by the heat treatment, and the structural symmetry of the copper complex coordinated with the phosphoric ester compound is changed, so that the absorption waveform and the absorption ability are changed. As a result, in addition to having high light transparency in the visible region, excellent near-infrared ray absorbing ability could be exhibited in the wavelength range of 900 to 1100 nm, which is the near-infrared region.

### BRIEF DESCRIPTION OF THE DRAWINGS

FIG. 1 is a schematic cross-sectional view illustrating an example of a configuration of a camera module having a solid-state imaging device having a near-infrared ray absorbing film of the present invention.

### EMBODIMENTS TO CARRY OUT THE INVENTION

The near-infrared ray absorbing composition of the present invention is a near-infrared ray absorbing composition containing an near-infrared absorber and a solvent, wherein the near-infrared absorber contains at least one of the component (A) and the component (B), and the compound having the structure represented by Formula (I) is contained in the component (A) or the component (B) in the range of 0.001 to 10% bay mass with respect to the total mass of the near-infrared ray absorbing composition. This feature is a technical feature common to the present invention according to each of the following embodiments.

In the near-infrared ray absorbing composition of the present invention, from the viewpoint that the target effect of the present invention may be further exhibited, it is preferable that the solid content concentration is in the range of 5 to 50% by mass in terms of making it possible to make the near-infrared ray absorbing composition to be fine particles and to realize high transmittance in the visible region.

In addition, when the transmittance at a wavelength of 850 nm is 1.0%, a near-infrared ray absorbing composition having a higher transmittance in the visible region and excellent near-infrared ray absorbing ability may be obtained by setting the transmittance at an average transmittance of 70% or more in the wavelength region of 450 to 550 nm.

In addition, it is preferable to contain a near-infrared absorption modifier having an absorption maximum wavelength in a wavelength range of 650 to 1000 nm in order to obtain a more excellent near-infrared ray absorption ability.

In addition, the near-infrared ray absorbing composition of the present invention realizes a near-infrared ray absorbing film having high transmittance in the visible region and excellent absorption characteristics in the near-infrared region, and an image sensor for a solid-state imaging device equipped with the same.

Hereinafter, the present invention and the constitution elements thereof, as well as configurations and embodiments to carry out the present invention, will be detailed in the following. In the present description, when two figures are used to indicate a range of value before and after “to”, these figures are included in the range as a lowest limit value and an upper limit value.

### <<Configuration of Near-Infrared Ray Absorbing Composition>>

The near-infrared ray absorbing composition of the present invention contains a near-infrared absorber and a solvent, wherein the near-infrared absorber contains at least one of the following component (A) and the following component (B), and a compound having a structure represented by the following Formula (I) is contained in the component (A) or the component (B) in the range of 0.001 to 10% by mass based on the total mass of the near-infrared ray absorbing composition.

Component (A): a component composed of at least one of a compound having a structure represented by the Formula (1) or Formula (2) with a compound having a structure represented by Formula (I) and a copper ion.

Component (B): a component composed of a copper complex obtained by reaction of at least one of a compound having a structure represented by Formula (1) or Formula (2) with a compound having a structure represented by Formula (I) and a copper compound.

O═P—(OH)₃ Formula (I):

Hereinafter, a high molecular weight phosphoric acid ester having a structure represented by the above Formula (1), which is a representative constituent of the near-infrared ray absorbing composition of the present invention, a low molecular weight phosphoric acid ester having a structure represented by the above Formula (2), a compound having a structure represented by the above Formula (I), a copper ion or a copper complex, and a solvent will be described. However, the present invention is not limited only to the configuration exemplified here.

### [Phosphoric Acid Ester]

The near-infrared ray absorbing composition of the present invention is characterized in that it contains at least one of a phosphoric acid ester having a structure represented by Formula (1) (hereinafter, also referred to as a phosphoric acid ester 1) or a phosphoric acid ester having a structure represented by Formula (2) (hereinafter, also referred to as a phosphoric acid ester 2).

### [Compound Having a Structure Represented by Formula (1): Phosphoric Acid Ester 1]

First, a phosphoric acid ester 1 having a structure represented by the following Formula (1) according to the present invention will be described.

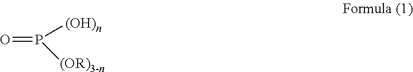

In the above Formula (1), R represents at least one group selected from the following Formulas (A) to (H) and (J), n represents 1 or 2, and when n represents 1, a plurality of R may be the same or different.

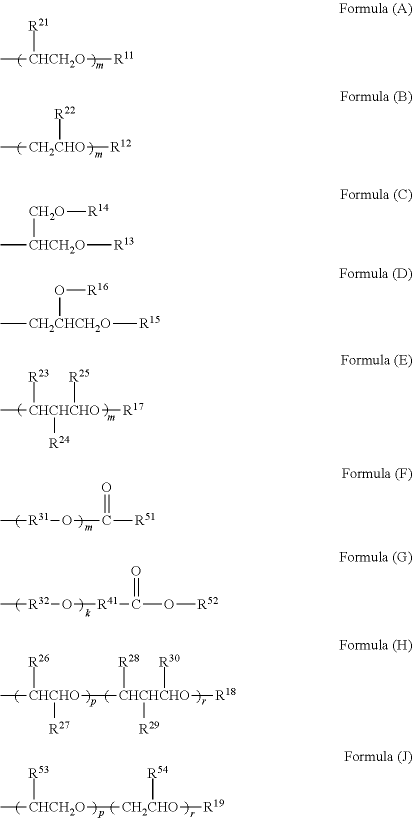

In the above Formulas (A) to (H) and (J), R¹¹ to R¹⁹ each respectively represent an alkyl group having 1 to 20 carbon atoms, an aryl group having 6 to 20 carbon atoms, or an aralkyl group having 6 to 20 carbon atoms (provided that at least one hydrogen atom bonded to a carbon atom constituting an aromatic ring may be substituted with an alkyl group having 1 to 6 carbon atoms, or a halogen); R²¹ to R³⁰ each respectively represent a hydrogen atom or an alkyl group having 1 to 4 carbon atoms; R³¹ and R³² each respectively represent an alkylene group having 1 to 6 carbon atoms; R⁴¹ represents an alkylene group having 1 to 10 carbon atoms; R⁵¹ and R⁵² each respectively represent an alkylene group having 1 to 20 carbon atoms; and R⁵³ and R⁵⁴ each respectively represent a hydrogen atom or an alkyl group having 1 to 4 carbon atoms, provided that one of R⁵³ and R⁵⁴ is always a hydrogen atom, and both of R⁵³ and R⁵⁴ are not a hydrogen atom at the same time; m represents an integer of 1 to 12, k represents an integer of 0 to 5, p represents an integer of 1 to 10, and r represents an integer of 1 to 10.

Examples of the alkyl group represented by R¹¹ to R¹⁹ include a methyl group, an ethyl group, an isopropyl group, an n-octyl group, an n-decyl group, an n-dodecyl group, and an n-stearyl group.

Examples of the aryl group represented by R¹¹ to R¹⁹ include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group and a biphenylyl group. Preferable examples are a phenyl group, a naphthyl group, a fluorenyl group, a phenanthryl group, a biphenylyl group, and a fluorenonyl group.

Examples of the aralkyl group represented by R¹¹ to R¹⁹ includes a benzyl group and a phenethyl group.

In the above Formulas (A) to (H) and (J), preferable are groups having a structure represented by Formulas (A), (B), (E), (F), (G), (H) and (J). Examples of the compound having such a structure include Exemplary compounds 1 to 6 shown below.

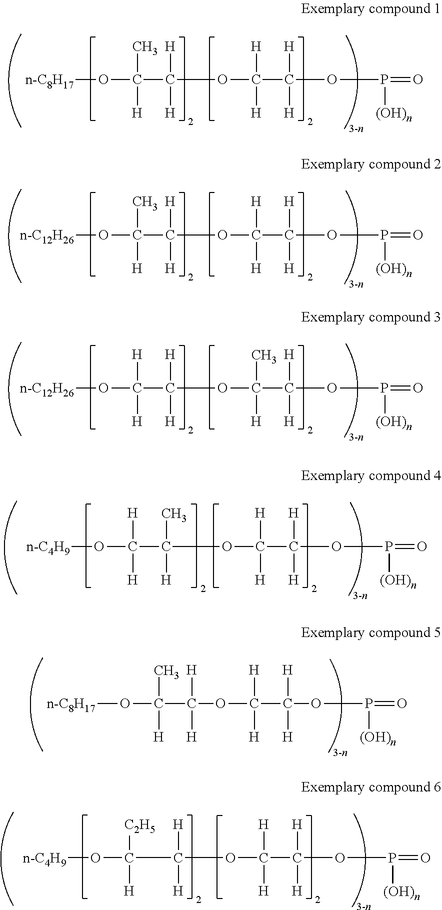

The compounds having the structures represented by these exemplary compounds 1 to 6 may be synthesized with reference to known methods described in, for example, JP-A 2005-255608, JP-A 2015-000396, JP-A 2015-000970, JP-A 2015-178072, JP-A 2015-178073, JP-A 2005-255608, and JP-A 4422866.

It is also possible to obtain these compounds as commercially available products as indicated in the following.

### (1) Manufactured by Dai-Ichi Kogyo Seiyaku Co., Ltd.

PLYSURF A212C: Polyoxyethylene tridecyl ether phosphate ester

PLYSURF A215C: Polyoxyethylene tridecyl ether phosphate ester

PLYSURF A208F: Polyoxyethylene alkyl(C8) ether phosphate esters

PLYSURF M208F: Polyoxyethylene alkyl(C8) ether phosphate ester-monoethanolamine salt

PLYSURF A208N: Polyoxyethylene alkyl(C12, 13) ether phosphate ester

PLYSURF A208B: Polyoxyethylene lauryl ether phosphate ester (oil-based dispersant)

PLYSURF A210B: Polyoxyethylene lauryl ether phosphate ester

PLYSURF A219B: Polyoxyethylene lauryl ether phosphate ester (water-based dispersant)

PLYSURF DB-01: Polyoxyethylene lauryl ether phosphate ester-monoethanolamine salt

PLYSURF AL: Polyoxyethylene styrene-modified phenyl ether phosphate ester

### (2) Manufactured by Nikko Chemicals Co., Ltd.

NIKKOL DDP-2: Polyoxyethylene alkyl(C12-C15) ether phosphate (2E.O. di(C12-15) pareth-2 phosphate)

NIKKOL DDP-4: Polyoxyethylene alkyl(C12-C15) ether phosphate (4E.O. di(C12-15) pareth-4 phosphate)

NIKKOL DDP-6: Polyoxyethylene alkyl(C12-C15) ether phosphate (6E.O. di(C12-15) pareth-6 phosphate)

NIKKOL DDP-8: Polyoxyethylene alkyl(C12-C15) ether phosphate (8E.O. di(C12-15) pareth-8 phosphate)

NIKKOL DDP-10: Polyoxyethylene alkyl(C12-C15) ether phosphate (10E.O. di(C12-15) pareth-10 phosphate)

NIKKOL DLP-10: Sodium polyoxyethylene lauryl ether phosphate (sodium dilaureth-10 phosphate)

NIKKOL DOP-8NV: Sodium polyoxyethylene oleyl ether phosphate (sodium dioleth-8 phosphate)

### (3) Manufactured by Adeka Corporation

ADECA COL TS-230E, ADECA COL CS-141E, ADECA COL CS1361E, ADECA COL CS-279 (each are an aromatic phosphate), ADECA COL PS-440E, ADECA COL PS-810E, ADECA COL PS-807, ADECA COL PS-984 (each are an aliphatic phosphate).

### [Compound Having a Structure Represented by Formula (2): Phosphoric Acid Ester 1]

Next, a phosphoric acid ester 2 having a structure represented by the following Formula (2) will be described.

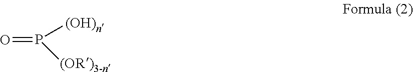

In the above Formula (2), R′ represents an alkyl group, an aryl group, an aralkyl group, or an alkenyl group each having 1 to 18 carbon atoms, and the total carbon number is in the range of 1 to 36. The alkyl group represented by R′ may be a branched, linear or ring structure. Examples thereof include a methyl group, an ethyl group, an n-propyl group, an i-propyl group, an n-butyl group, a t-butyl group, a cyclohexyl group, an n-octyl group, a 2-ethylhexyl group, and an n-dodecyl group.

Examples the aryl group represented by R′ include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group and a biphenylyl group. Preferable examples are a phenyl group, a naphthyl group, a fluorenyl group, a phenanthryl group, a biphenylyl group, and a fluorenonyl group.

Examples of the aralkyl group represented by R′ include a benzyl group and a phenethyl group.

Examples of the alkenyl group represented by R′ include a vinyl group, an allyl group, a butenyl group, a pentenyl group, and a hexenyl group.

In the above Formula (2), n′ represents 1 or 2, and when n′ represents 1, a plurality of R′ may be the same or different.

Examples of the representative phosphoric acid ester 2 having a structure represented by Formula (2) are as follows.

(1) Phosphoric acid methyl ester

(2) Phosphoric acid ethyl ester

(3) Phosphoric acid n-propyl ester

(4) Phosphoric acid i-propyl ester

(5) Phosphoric acid n-butyl ester

(6) Phosphoric acid t-butyl ester

(7) Phosphoric acid n-pentyl ester

(8) Phosphoric acid n-hexyl ester

(9) Phosphoric acid 2-ethylhexyl ester

(10) Phosphoric acid n-heptyl ester

(11) Phosphoric acid n-octyl ester

(12) Phosphoric acid cyclohexyl ester

(13) Phosphoric acid n-dodecyl ester

(14) Phosphoric acid stearyl ester

(15) Phosphoric acid phenyl ester

(16) Phosphoric acid benzyl ester

(17) Phosphoric acid 2-methacryloxyethyl ester

### [Copper Complex]

The present invention is characterized by containing a component composed of a copper complex obtained by reacting at least one of a compound having a structure represented by Formula (1) or Formula (2) with copper ions or a copper compound.

In the invention present invention, as a copper salt used for forming a copper complex composed of a high molecular weight phosphoric acid ester 1 having a structure represented by Formula (1) according to the present invention and a copper ion, or as a copper salt used for forming the copper complex composed of a low molecular weight phosphoric acid ester 2 having a structure represented by Formula (2) and a copper ion, a copper salt capable of supplying divalent copper ions is used. Examples thereof include copper salts of organic acids such as anhydrous copper acetate, anhydrous copper formate, anhydrous copper stearate, anhydrous copper benzoate, anhydrous copper acetoacetate, anhydrous copper ethylacetoacetate, anhydrous copper methacrylate, anhydrous copper pyrophosphate, anhydrous copper naphthenate, anhydrous copper citrate, hydrates of copper salts of the organic acids; copper salts of inorganic acids such as copper oxide, copper chloride, copper sulfate, copper nitrate, copper phosphate, basic copper sulfate, and basic copper carbonate, hydrates of copper salts of the inorganic acids; and copper hydroxide.

A copper complex composed of a phosphoric acid ester having a structure represented by Formula (1) according to the present invention and copper ions, and a copper complex composed of a phosphoric acid ester having a structure represented by Formula (2) and copper ions may be synthesized by applying the method described in Japanese Patent No. 4422866.

### [Properties of Phosphoric Acid Ester Copper Complex]

The phosphoric acid group of the phosphoric acid ester according to the present invention binds to a copper ion by a coordination bond and/or an ionic bond, and the copper ion is dissolved or dispersed in the near-infrared ray absorbing film in a state surrounded by the phosphoric acid ester. The near-infrared light is selectively absorbed by the electronic transition between the d orbits of the copper ions. Further, the content of phosphorus atoms in the near-infrared ray absorption film is preferably 1.5 or less with respect to 1 mol of copper ions, and more preferably 0.4 to 1.3. That is, when the content ratio (hereinafter, referred to as “P/Cu”) is 0.4 to 1.3 in terms of molar ratio, it was confirmed to be very suitable from the viewpoint that the moisture resistance of the near-infrared ray absorbing film and the dispersibility of copper ions in the near-infrared light absorbing layer are improved.

When P/Cu is less than 0.4 in terms of molar ratio, copper ions become excessive with respect to the coordinating phosphate ester, and copper ions tend to be hardly uniformly dispersed in the near-infrared ray absorbing film. On the other hand, when P/Cu exceeds 1.3 in terms of molar ratio, devitrification tends to occur when the thickness of the near-infrared ray absorbing film is reduced to increase the content of copper ions, and this tendency becomes particularly remarkable in an environment of high temperature and high humidity. Further, it is more preferable that P/Cu is 0.8 to 1.3 in terms of molar ratio. When this molar ratio is 0.8 or more, dispersibility of copper ions in the resin may be reliably and sufficiently increased.

Further, when the content ratio of copper ions in the near-infrared ray absorbing film is less than the above lower limit value, it tends to be difficult to obtain a sufficient near-infrared light absorbing property when the thickness of the near-infrared ray absorbing film is made thinner than about 1 mm. On the other hand, when the content ratio of copper ions exceeds the above upper limit value, it tends to be difficult to disperse copper ions in the near-infrared ray absorbing film.

### [Compound Having Structure Represented by Formula (I)]

In the near-infrared ray absorbing composition of the present invention, along with the phosphoric acid ester 1 having a structure represented by Formula (1) or the phosphoric acid ester 2 having a structure represented by Formula (2), a compound having a structure represented by Formula (I) is contained in the range of 0.001 to 10 mass % with respect to the total mass of the near-infrared ray absorbing composition.

O═P—(OH)₃ Formula (I):

The compound having a structure represented by the above Formula (I) is specifically phosphoric acid, and by being present in the near-infrared ray absorbing composition in the range of a specific content ratio, it is possible to convert the absorption wavelength with high accuracy by conducting a heat treatment. In particular, the effect of improving the absorption performance in the wavelength range of 900 to 1100 nm is exhibited.

The present invention is characterized in that the content of the phosphoric acid represented by Formula (I) is in the range of 0.001 to 10% by mass with respect to the total mass of the near-infrared ray absorbing composition. More preferably, it is in the range of 0.001 to 1.0% by mass, particularly preferably, it is in the range of 0.001 to 0.1% by mass.

When the content of phosphoric acid is 0.001% by mass or more, the absorption performance in the wavelength range of 900 to 1100 nm may be improved. When it is 10% by mass or less, the dispersibility is excellent and a good average particle size may be obtained.

### [Solvent]

Solvents applicable to the preparation of the near-infrared ray absorbing compositions of the present invention will be described.

The solvent which may be used in the near-infrared ray absorbing composition of the present invention is not particularly limited. Examples thereof include a hydrocarbon-based solvent, and more preferably an aliphatic hydrocarbon-based solvent, an aromatic hydrocarbon-based solvent, and a halogen-based solvent.

Examples of the aliphatic hydrocarbon-based solvent include acyclic aliphatic hydrocarbon-based solvents such as hexane and heptane, cyclic aliphatic hydrocarbon-based solvents such as cyclohexane, alcohol-based solvents such as methanol, ethanol, n-propanol, and ethylene glycol, ketone-based solvents such as acetone, methyl ethyl ketone, and ether-based solvents such as diethyl ether, diisopropyl ether, tetrahydrofuran, 1,4-dioxane, ethylene glycol monomethyl ether, and propylene glycol monomethyl ether acetate (PGMEA). Examples of the aromatic hydrocarbon-based solvent include toluene, xylene, mesitylene, cyclohexylbenzene, and isopropylbiphenyl. Examples of the halogen-based solvent include methylene chloride, 1,1,2-trichloroethane, and chloroform. Further, solvents such as anisole, 2-ethylhexane, sec-butyl ether, 2-pentanol, 2-methyltetrahydrofuran, 2-propylene glycol monomethyl ether, 2,3-dimethyl-1,4-dioxane, sec-butylbenzene, and 2-methylcyclohexylbenzene may be mentioned. Among them, ether-based solvents are preferred, in particular, tetrahydrofuran is preferred from the viewpoint of boiling point and solubility.

### [Solid Content Concentration]

In the near-infrared ray absorbing composition of the present invention, the solid content concentration is preferably in the range of 5 to 50% by mass, more preferably in the range of 10 to 40% by mass, and further preferably in the range of 20 to 30% by mass. When the solid content concentration is 5% by mass or more, the absorption performance in the wavelength range of 900 to 1100 nm may be improved, and when it is 50% by mass or less, the dispersibility is excellent and a good average particle size may be obtained.

### [Near-Infrared Absorption Modifier]

In the near-infrared ray absorbing composition of the present invention, it is preferable to add at least one near-infrared absorption modifier having an absorption maximum wavelength in a wavelength range of 650 to 1000 nm as an additive for adjusting an absorption waveform from the viewpoint of obtaining required spectral characteristics. As the near-infrared absorption modifier applied to the present invention, it is preferable to apply a near-infrared absorption dye having an absorption maximum wavelength in a wavelength range of 650 to 1000 nm. For example, a copper compound and an organic dye are cited.

Examples of the near-infrared ray absorbing dye which is an organic dye suitable for the present invention include a cyanine dye, a squarylium dye, a croconium dye, an azo dye, an anthraquinone dye, a naphthoquinone dye, a phthalocyanine dye, a naphthalocyanine dye, a quaterrylene dye, and a dithiol metal complex dye. Among them, a phthalocyanine dye, a naphthalocyanine dye, and a quaterrylene dye are particularly preferred in terms of sufficiently absorbing near-infrared rays, high visible light transmittance, and high heat resistance.

Specific examples of the phthalocyanine compound include the compounds described in, for example, JP-A 2000-26748, JP-A 2000-63691, JP-A 2001-106689, JP-A 2004-149752, JP-A 2004-18561, JP-A 2005-220060, JP-A 2007-169343, JP-A 2016-204536, and JP-A 2016-218167. These compounds may be synthesized according to the method described in these publications.

Specific examples of the quaterrylene-based dye include the compounds described in, for example, JP-A 2008-009206 and JP-A 2011-225608, and they may be synthesized according to the method described in these publications.

The near-infrared ray absorbing dye is also available as a commercial product. Examples thereof which may be mentioned include: FDR002, FDR003, FDR004, FDR005, and FDN001 (manufactured by Yamada Chemical Industry Co., Ltd.); Excolor TX-EX720, and Excolor TX-EX708K (manufactured by Nippon Schokubai Co., Ltd.); Lumogen IR765, and Lumogen IR788 (manufactured by BASF Co., Ltd.); ABS694, IRA735, IRA742, IRA751, IRA764, IRA788, and IRA800 (manufactured by Exciton Co., Ltd.); Epolight 5548, Epolight 5768 (manufactured by Aako Co., Ltd.); VIS680E, VIS695A, NIR700B, NIR735B, NIR757A, NIR762A, NIR775B, NIR778A, NIR783C, NIR783I, NIR790B, and NIR795A (manufactured by QCR Solutions Corp); DLS740A, DLS740B, DLS740C, DLS744A, DLS745B, DLS771A, DLS774A, DLS774B, DLS775A, DLS775B, DLS780A, DLS780C, and DLS782F (manufactured by Crystalin Co., Ltd.); and B4360, B4361, D4773, and D5013 (manufactured by Tokyo Chemical Industry Co., Ltd.).

The amount of the near-infrared ray absorbing dye to be added is preferably within a range of 0.01 to 0.1% by mass based on 100% by mass of the near-infrared absorber constituting the near-infrared ray absorbing composition.

When the amount of the near-infrared ray absorbing dye added is 0.01% by mass or more based on 100% by mass of the near-infrared absorber, the near-infrared ray absorption may be sufficiently increased, and when the amount is 0.1% by mass or less, the visible light transmittance of the obtained near-infrared ray absorbing composition is not impaired.

### [UV Absorber]

In the near-infrared ray absorbing composition of the present invention, it is preferable to further contain an ultraviolet absorber in addition to a near-infrared absorber and a solvent from the viewpoint of spectroscopic characteristics and light resistance.

The ultraviolet absorption is not particularly limited, and examples thereof include a benzotriazole-based ultraviolet absorber, a benzophenone-based ultraviolet absorber, a salicylic ester-based ultraviolet absorber, a cyanoacrylate-based ultraviolet absorber, and a triazine-based ultraviolet absorber.

Examples of the benzotriazole-based ultraviolet absorber include 5-chloro-2-(3,5-di-oxybutyl-2-hydroxylphenyl)2H-benzotriazole, and (2-2H-benzotriazole-2-yl)-6-(linear and side chain dodecyl)-4-methylphenol. Further, a benzotriazole-based ultraviolet absorber may be obtained as a commercially available product. Examples thereof are a TINUVIN series such as TINUVIN 109, TINUVIN 171, TINUVIN 234, TINUVIN 326, TINUVIN 327, TINUVIN 328, and TINUVIN 928. All of them are commercially available products manufactured by BASF Co., Ltd.

Examples of the benzophenone-based ultraviolet absorber include 2-hydroxy-4-benzyloxybenzophenone, 2,4-benzyloxybenzophenone, 2,2′-dihydroxy-4-methoxybenzophenone, 2-hydroxy-4-methoxy-5-sulfobenzophenone, and bis(2-methoxy-4-hydroxy-5-benzoylphenylmethane).

Examples of the salicylic ester-based ultraviolet absorber include phenyl salicylate and p-tert-butyl salicylate.

Examples of the cyanoacrylate-based ultraviolet absorber include 2′-ethylhexyl-2-cyano-3,3-diphenylacrylate and ethyl-2-cyano-3-(3′,4′-methylenedioxyphenyl)-acrylate.

Examples of the triazine-based ultraviolet absorber include 2-(2′-hydroxy-4′-hexyloxyphenyl)-4,6-diphenyltriazine. As a commercially available product of the triazine-based ultraviolet absorber, for example, manufactured by TINUVIN477 (BASF Co., Ltd.) is mentioned.

The amount of the ultraviolet absorber to be added is preferably within a range of 0.1 to 5.0% by mass based on 100% by mass of the near-infrared absorber constituting the near-infrared ray absorbing composition.

When the amount of the ultraviolet absorber added is 0.1% by mass or more based on 100% by mass of the near-infrared absorber, the light resistance may be sufficiently increased, and when the amount is 5.0% by mass or less, the visible light transmittance of the obtained near-infrared ray absorbing composition is not impaired.

### [Spectral Characteristics]

In the near-infrared ray absorbing composition of the present invention or the near-infrared absorptive film to which the composition is applied, when the transmittance at a wavelength of 850 nm is 1.0%, the average transmittance in the wavelength region of 450 to 550 nm is preferably 70%.

When the near-infrared ray absorbing composition having the constitution defined in the present invention is made to have a transmittance of 1.0% at a wavelength of 850 nm in the near-infrared region, that is, under a condition of high near-infrared ray absorbing ability, it has a high transmittance characteristic that the average transmittance is 70% or more in the wavelength region of 450 to 550 nm which is a visible region.

The spectral transmittance characteristics may be obtained by the following method, for example.

The near-infrared ray absorbing composition of the present invention or a near-infrared ray absorbing film to which it is applied is used as a measurement sample. A spectrophotometer V-570 manufactured by JASCO Corporation is used as a measuring device to measure the spectral transmittance in the wavelength range of 300 to 1200 nm. Then, under the condition that the transmittance at a wavelength of 850 nm is 1.0%, the spectral transmittance at 450 to 550 nm in the visible region is measured, and the average transmittance is obtained.

### <<Near-Infrared Ray Absorbing Film and its Application Field>>

In the present invention, it is one characteristic that a near-infrared ray absorbing film is formed using the near-infrared ray absorbing composition of the present invention.

The near-infrared ray absorbing film of the present invention is formed by adding a matrix resin to a near-infrared ray absorbing composition according to the present invention, and dispersing fine particles of a copper complex. As an additive for adjusting the absorption waveform, at least one kind of the near-infrared dye having an absorption maximum wavelength in a wavelength range of 650 to 1000 nm may be added.

A coating liquid for forming a near-infrared ray absorbing film having the above configuration is applied onto a substrate by a spin coating or a wet coating method using a dispenser to form a near-infrared ray absorbing film. Thereafter, a predetermined heat treatment is performed on this coating film to cure the coating film to form a near-infrared ray absorbing film.

The matrix resin used for forming the near-infrared ray absorbing film is a resin which is transparent to visible light and near-infrared light and may disperse fine particles of a copper complex. The copper complex is a substance having a relatively low polarity and is well dispersed in a hydrophobic material. Therefore, as the matrix resin for forming the near-infrared ray absorbing film, a resin having an acrylic group, an epoxy group, or a phenyl group may be used. Among them, it is particularly preferable to use a resin having a phenyl group as a matrix resin of a near-infrared ray absorbing film. In this case, the matrix resin of the near-infrared ray absorbing film has high heat resistance. In addition, a polysiloxane silicone resin has advantageous characteristics as a material for an image sensor for a solid-state imaging device because it is difficult to thermally decompose, has high transparency to visible light and near-infrared light, and has high heat resistance. Therefore, it is also preferable to use a polysiloxane as a matrix resin of a near-infrared ray absorbing film. As a polysiloxane that may be used as a matrix resin for near-infrared ray absorbing films, it is available as a commercial product. Examples thereof include KR-255, KR-300, KR-2621-1, KR-211, KR-311, KR-216, KR-212 and KR-251, which are silicone resins manufactured by Shin-Etsu Chemical Co., Ltd.

### (Other Additives)

Other additives may be applied to the near-infrared ray absorbing film of the present invention within a range not impairing the object effect of the present invention. Examples thereof include a sensitizer, a crosslinking agent, a curing accelerator, a filler, a thermal curing accelerator, a thermal polymerization inhibitor, and a plasticizer. Further, an adhesion accelerator on the surface of the base material and other auxiliary agents (e.g., conductive particles, a filler, a defoaming agent, a flame retardant, a leveling agent, a release accelerator, an antioxidant, a perfume, a surface tension modifier, and a chain transfer agent) may be used in combination.

By appropriately incorporating these components, it is possible to adjust the desired properties such as stability and physical properties of the near-infrared ray absorbing film.

These components may be referred to the contents described in the paragraph 183 of JP-A 2012-003225, the paragraphs 101-102 of JP-A 2008-250074, the paragraphs 103-104 of JP-A 2008-250074, and the paragraphs 107-109 of JP-A 2008-250074, for example.

Since the near-infrared ray absorbing composition of the present invention may be a wet coating liquid, a near-infrared ray absorbing film (for example, a near-infrared ray cut filter) may be easily manufactured by a process including a simple coating step of forming a film by spin coating.

### <<Application to Image Sensor for Solid-State Imaging Device>>

The near-infrared ray absorbing film of the present invention is suitably applied to the following devices. Examples of the application are: a visibility correction member for CCD, CMOS, or other light receiving element, a photometric member, a heat ray absorbing member, a composite optical filter, a lens member (eyeglasses, sunglasses, goggles, optical system, and optical waveguide system), a fiber member (optical fiber), a noise cut member, a display cover or a display filter such as a plasma display front plate, a projector front plate, a light source heat ray cutting member, a color tone correcting member, an illumination brightness adjusting member, an optical element (optical amplifying element, wavelength conversion element), a Faraday element, an optical communication function device such as an isolator, an optical disk element.

The applications of the near-infrared ray absorbing film having a near-infrared ray absorbing composition of the present invention are suitable, in particular, for a near-infrared ray cut filter on the light-receiving side of the solid-state imaging device substrate (for example, for near-infrared ray cut filter for a wafer-level lens), and for a near-infrared ray cut filter on the back side of the solid-state imaging device substrate (the side opposite to the light-receiving side). It is characterized in that it is applied to the image sensor for a solid-state imaging device.

By applying the near-infrared ray absorbing film of the present invention to an image sensor for a solid-state imaging device, it is possible to improve the visible portion transmittance, the near-infrared ray absorbing efficiency, and the heat and humidity resistance.

Specifically, the near-infrared ray absorbing film (near-infrared ray cut filter) of the present invention is provided on an image sensor for a solid-state imaging device.

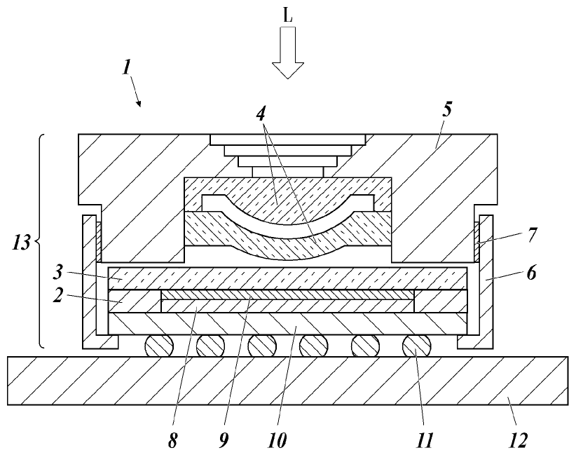

FIG. 1 is a schematic cross-sectional view showing a configuration of a camera module including a solid-state imaging device including an infrared ray cut filter which is a near-infrared ray absorbing film of the present invention.

The camera module 1 shown in FIG. 1 is connected to a circuit board 12 which is a mounting board via solder balls 11 which are a connecting member.

More specifically, the camera module 1 is configured with composing a solid-state imaging device substrate 10 having an imaging device section 13 on a first main surface of a silicon substrate, a flattening layer 8 provided on a first main surface side (light receiving side) of the solid-state imaging device substrate 10, a near-infrared ray cut filter (near-infrared ray absorbing film) 9 provided on the flattening layer 8, a glass substrate 3 (light transmitting substrate) disposed above the near-infrared ray cut filter 9, a lens holder 5 arranged above the glass substrate 3 and having an image pickup lens 4 in the inner space thereof, a light and electromagnetic shield 6 arranged so as to surround the solid-state imaging device substrate 10 and the glass substrate 3. Each member is adhered by adhesives 2 and 7.

The present invention is a method of manufacturing a camera module having a solid-state imaging device substrate and an infrared ray cut filter disposed on a light-receiving side of the solid-state imaging device substrate, and it is possible to form a near-infrared ray absorbing film by spin-coating the infrared ray absorbing liquid composition of the present invention on the light-receiving side of the solid-state imaging device substrate.

Therefore, in the camera module 1, for example, a near-infrared ray absorbing film is formed by spin-coating the near-infrared ray absorbing composition of the present invention on the flattening layer 8 to form the infrared ray cut filter 9.

In the camera module 1, the incident light L from the outside is sequentially transmitted through the imaging lens 4, the glass substrate 3, the infrared ray cut filter 9, and the flattening layer 8, and then reaches the imaging device section of the solid-state imaging device substrate 10.

Further, the camera module 1 is connected to the circuit board 12 via the solder balls 11 (connecting material) on the second main surface side of the solid-state imaging device substrate 10.

### EXAMPLES

Hereinafter, the present invention will be specifically described by way of examples, but the present invention is not limited thereto. In the examples, “parts” or “%” is used, but unless otherwise specified, it indicates “parts by mass” or “% by mass”. Each operation was performed at room temperature (25° C.) unless otherwise specified.

### Example 1

### <<Preparation of Near-Infrared Ray Absorbing Composition>>

### (Preparation of Near-Infrared Ray Absorbing Composition 1)

A near-infrared ray absorbing composition 1 was prepared according to the following method.

1.46 g of copper acetate and 58.54 g of tetrahydrofuran (abbreviation: THF) as a solvent were mixed, and copper acetate was dissolved using an ultrasonic wave irradiator, and filtration operation was performed to remove insoluble copper acetate. Thus, a liquid A containing a solvent (THF) was prepared.

Then, 4.0 g of THF was added to 2.0 g of a PLYSURF A208F (trade name) manufactured by Dai-ichi Kogyo Seiyaku Co., Ltd., which is a compound having a structure represented by Formula (1), and stirred to prepare a solution B.

Further, to 0.62 g of ethyl phosphate, 0.016 g of phosphoric acid, and 4.00 g of THF were added and stirred to prepare a liquid C.

Then, while stirring the liquid A, the liquid B and the liquid C were sequentially added, and the mixture was stirred at room temperature for 16 hours. Then the mixture was heated to remove THF as a solvent, and the solid content ratio (solid content: copper, ethyl phosphate, and PLYSURF A208F) was adjusted to be 20% by mass.

In this way, a near-infrared ray absorbing composition 1 containing an ethyl phosphate copper complex formed with ethyl phosphate as a compound represented by Formula (2) and PLYSURF A208F as a compound represented by Formula (1), and having a content of phosphoric acid of 0.10% by mass was prepared.

### (Preparation of Near-Infrared Ray Absorbing Compositions 2 to 5)

Near-infrared ray absorbing compositions 2 to 5 were prepared in the same manner as the preparation of the near-infrared ray absorbing composition 1, except that the content of phosphoric acid was respectively changed to 0.001 mass %, 0.01 mass %, 1.00 mass %, and 10.0 mass %.

### (Preparation of Near-Infrared Ray Absorbing Compositions 6 to 9)

Near-infrared ray absorbing compositions 6 to 9 were prepared in the same manner as the preparation of the near-infrared ray absorbing composition 1, except that by appropriately adjusting the content of THF, the solid content ratio was respectively changed to 3.0 mass %, 5.0 mass %, 50.0 mass %, and 60.0 mass %.

### (Preparation of Near-Infrared Ray Absorbing Composition 10)

A near-infrared ray absorbing composition 10 was prepared in the same manner as the preparation of the near-infrared ray absorbing composition 1, except that PLYSURF A208F, which is a compound according to Formula (1), was removed, and the amount of ethyl phosphate was set to be 1.13 g.

### (Preparation of Near-Infrared Ray Absorbing Compositions 11 to 15)

Near-infrared ray absorbing compositions 11 to 15 were prepared in the same manner as the preparation of the near-infrared ray absorbing composition 10, except that the ethyl phosphate, which is a compound according to Formula (2), was respectively changed to the phosphoric acid ester (the same mole) described in Table I.

### (Preparation of Near-Infrared Ray Absorbing Composition 16)

A near-infrared ray absorbing composition 16 was prepared in the same manner as the preparation of the near-infrared ray absorbing composition 1, except that ethyl phosphate, which is a compound according to Formula (2), was removed, and an amount of PLYSURF A208F was set to be 4.41 g.

### (Preparation of Near-Infrared Ray Absorbing Compositions 17 to 20)

Near-infrared ray absorbing compositions 17 to 20 were prepared in the same manner as the preparation of the near-infrared ray absorbing composition 16, except that the compound according to Formula (2) was respectively changed to the phosphoric acid ester (the same mole) described in Table I.

### (Preparation of Near-Infrared Ray Absorbing Compositions 21 to 24)

Near-infrared ray absorbing compositions 21 to 24 were prepared in the same manner as the preparation of the near-infrared ray absorbing composition 1, except that the compound according to Formula (1) was respectively changed to the phosphoric acid ester (the same mole) described in Table I.

### (Preparation of Near-Infrared Ray Absorbing Compositions 25 to 35)

Near-infrared ray absorbing compositions 25 to 35 were prepared in the same manner as the preparation of the near-infrared ray absorbing composition 1, except that the compound according to Formula (1) was respectively changed to the phosphoric acid ester (the same mole) described in Table I, and the compound according to Formula (2) was respectively changed to the phosphoric acid ester (the same mole) described in Table II.

### (Preparation of Near-Infrared Ray Absorbing Composition 36)

A near-infrared ray absorbing composition 36 was prepared in the same manner as the preparation of the near-infrared ray absorbing composition 1, except that, after stirring at room temperature for 16 hours, 0.60 mg of FDR004 (maximum absorption wavelength: 716 nm, manufactured by Yamada Chemical Industry Co., Ltd.) as a near-infrared ray absorbing dye shown in Table II was added as a near-infrared absorbing modifier, and 15.82 g of anisole was further added. Then, the mixture was heated to volatilize THF and anisole as a solvent so as to have a solid content of 20% by mass.

### (Preparation of Near-Infrared Ray Absorbing Composition 37)

A near-infrared ray absorbing composition 37 was prepared in the same manner as the preparation of the near-infrared ray absorbing composition 1, except that, after stirring at room temperature for 16 hours, 0.60 mg of FDR004 and 1.43 mg of Lumogen IR765 (BASF Co., Ltd.) as a near-infrared ray absorbing dye shown in Table II were added as a near-infrared absorbing modifier, and 15.82 g of anisole was further added. Then the mixture was heated to volatilize THF and anisole as a solvent so as to have a solid content of 20% by mass.

### (Preparation of Near-Infrared Ray Absorbing Composition 38)

A near-infrared ray absorbing composition 38 was prepared in the same manner as the preparation of the near-infrared ray absorbing composition 27, except that, after stirring at room temperature for 16 hours, 0.60 mg of FDR004 and 1.43 mg of Lumogen IR765 (BASF Co., Ltd.) as a near-infrared ray absorbing dye shown in Table II were added as a near-infrared absorbing modifier, and 15.82 g of anisole was further added. Then, the mixture was heated to volatilize THF and anisole as a solvent so as to have a solid content of 20% by mass.

### (Preparation of Near-Infrared Ray Absorbing Composition 39)

A near-infrared ray absorbing composition 39 was prepared in the same manner as the preparation of the near-infrared ray absorbing composition 28, except that, after stirring at room temperature for 16 hours, 0.60 mg of FDR004 and 1.43 mg of Lumogen IR765 (BASF Co., Ltd.) as a near-infrared ray absorbing dye shown in Table II were added as a near-infrared absorbing modifier, and 15.82 g of anisole was further added. The, the mixture was heated to volatilize THF and anisole as a solvent so as to have a solid content of 20% by mass.

(Preparation of near-infrared ray absorbing composition 40) A near-infrared ray absorbing composition 40 of Comparative Example was prepared in the same manner as the preparation of the near-infrared ray absorbing composition 1, except that the amount of phosphoric acid added was changed to 9.25 g and the content of phosphoric acid was changed to 15.0% by mass.
(Preparation of near-infrared ray absorbing composition 41) A near-infrared ray absorbing composition 41 of Comparative Example was prepared in the same manner as the preparation of the near-infrared ray absorbing composition 10, except that ethyl phosphate ester, which is a compound according to Formula (2), was changed to mono(2-hydroxylethylmethacrylate) phosphate, and phosphoric acid was removed.
(Preparation of near-infrared ray absorbing composition 42) A near-infrared ray absorbing composition 42 of Comparative Example was prepared in the same manner as the preparation of the near-infrared ray absorbing composition 1, except that phosphoric acid was removed.
(Preparation of near-infrared ray absorbing composition 43) A near-infrared ray absorbing composition 43 of Comparative Example was prepared in the same manner as the preparation of the near-infrared ray absorbing composition 10, except that phosphoric acid was removed.
(Preparation of near-infrared ray absorbing composition 44) A near-infrared ray absorbing composition 43 of Comparative Example was prepared in the same manner as the preparation of the near-infrared ray absorbing composition 16, except that phosphoric acid was removed.

Details of each compound used in the preparation of the near-infrared ray absorbing composition described by abbreviations in Table I and Table II are as follows.

### (Compounds Having a Structure Represented by Formula (1))

A208F: PLYSURF A208F (polyoxyethylene alkyl(C8) ether phosphate ester manufactured by Dai-ichi Kogyo Seiyaku Co., Ltd.)

A208N: PLYSURF A208N (polyoxyethylene alkyl(C12, 13) ether phosphate ester manufactured by Dai-ichi Kogyo Seiyaku Co., Ltd.)

A215C: PLYSURF A215C (polyoxyethylene tridecyl phosphate ester manufactured by Dai-ichi Kogyo Seiyaku Co., Ltd.)

DDP-2: NIKKOL DDP-2 (polyoxyethylene alkyl(C12-C15) ether phosphate (2E.O. di(C12-15) pareth-2 phosphate manufactured by Nikko Chemicals Co., Ltd.)

DDP-4: NIKKOL DDP-4 (polyoxyethylene alkyl(C12-C15) ether phosphate (4E.O. di(C12-15) pareth-4 phosphate manufactured by Nikko Chemicals Co., Ltd.)

### (Compounds Having a Structure Represented by Formula (2))

*1: Mono(2-hydroxyethylmethacrylate) phosphate

### <<Evaluation of Near-Infrared Ray Absorbing Compositions>>

The average particle size, the transmittance in the visible region (550 nm) and the transmittance in the near-infrared region (1000 nm) were measured for each of the above-prepared near-infrared ray absorbing compositions according to the following method.

### (Measurement of Average Particle Size of Copper Complex Particles)

For the above prepared near-infrared ray absorbing compositions 1 to 44, each evaluation sample A diluted with toluene was prepared so that the particle concentration (solid content concentration) of the copper complex particles as particles became 1.0% by mass.

Next, the mean particle size of each of the evaluation samples A was measured by a dynamic-light scattering method using a zeta-potential/particle-size measurement system ELSZ-1000ZS (manufactured by Otsuka Electronics Co., Ltd.) as a measurement device.

The average particle size immediately after preparation measured by the above method was ranked according to the following criteria.

AA: Average particle size is less than 50 nm

BB: Average particle size is in the range of 50 nm or more and less than 100 nm

CC: Average particle size is in the range of 100 nm or more and less than 200 nm

DD: Average particle size is 200 nm or more.

### [Measurement of Spectral Transmittance]

Spectral transmittance in a wavelength range of 300 nm to 1200 nm was measured by a spectrophotometer V-570 (manufactured by JASCO Corporation) as a measuring device using the respective evaluation sample A prepared for measuring the above-mentioned average particle size. Next, the spectral transmittance at 550 nm as the visible region and the spectral transmittance at 1000 nm as the near-infrared region were evaluated as follows.

### (Evaluation of Transmittance 1 in the Visible Region)

The transmittance of the near-infrared ray absorbing composition measured by the above method at 550 nm was ranked according to the following criteria, and evaluation of the transmittance 1 in the visible region was performed.

AA: The transmittance is 90% or more

BB: The transmittance is 80% or more and less than 90%

CC: The transmittance is 70% or more and less than 80%

DD: The transmittance is less than 70%

(Evaluation of transmittance 2 in the near-infrared region) The transmittance at 750 nm of the near-infrared ray absorbing composition measured by the above method was ranked according to the following criteria, and the transmittance 2 in the near-infrared region was evaluated.

AA: Transmittance is less than 5%

BB: The transmittance is 5% or more and less than 15%.

CC: The transmittance is 15% or more and less than 25%.

DD: The transmission rate is 25% or more.

### (Evaluation of Transmittance 3 in the Near-Infrared Region)

The transmittance at 1000 nm of the near-infrared ray absorbing composition measured by the above method was ranked according to the following criteria, and the transmittance 3 in the near-infrared region was evaluated.

AA: The transmittance is less than 3%

BB: The transmittance is 3% or more and less than 8%.

CC: The transmittance is 8% or more and less than 15%.

DD: The transmission rate is 15% or more.

TABLE I

| | | | | | Formula (I) | | | | | | | |
|---|---|---|---|---|---|---|---|---|---|---|---|---|
| | Formula (1) | | Formula (2) | | Compound | Solid | Near- | Evaluation result | | | | |
| | compound | | compound | | Added | Content | infrared | Average | Transmit- | Transmit- | Transmit- | |
| | | Mole | | Mole | amount | Ratio | absorption | Particle | tance 1 | tance 2 | tance 3 | |
| *1 | Species | number | Species | number | (mass %) | (mass %) | modifier | size | (550 nm) | (750 nm) | (1000 nm) | Remarks |
| 1 | A208F | 0.54 | *2 | 0.65 | 0.10 | 20.0 | — | AA | AA | BB | AA | *8 |
| 2 | A208F | 0.54 | *2 | 0.65 | 0.001 | 20.0 | — | AA | BB | BB | BB | *8 |
| 3 | A208F | 0.54 | *2 | 0.65 | 0.01 | 20.0 | — | AA | AA | BB | AA | *8 |
| 4 | A208F | 0.54 | *2 | 0.65 | 1.00 | 20.0 | — | BB | AA | BB | AA | *8 |
| 5 | A208F | 0.54 | *2 | 0.65 | 10.0 | 20.0 | — | BB | BB | BB | AA | *8 |
| 6 | A208F | 0.54 | *2 | 0.65 | 0.10 | 3.0 | — | AA | AA | AA | BB | *8 |
| 7 | A208F | 0.54 | *2 | 0.65 | 0.10 | 5.0 | — | AA | AA | AA | BB | *8 |
| 8 | A208F | 0.54 | *2 | 0.65 | 0.10 | 50.0 | — | BB | BB | BB | AA | *8 |
| 9 | A208F | 0.54 | *2 | 0.65 | 0.10 | 60.0 | — | BB | BB | BB | BB | *8 |
| 10 | — | — | *2 | 1.19 | 0.10 | 20.0 | — | BB | BB | BB | AA | *8 |
| 11 | — | — | *3 | 1.19 | 0.10 | 20.0 | — | BB | BB | BB | AA | *8 |
| 12 | — | — | *4 | 1.19 | 0.10 | 20.0 | — | BB | BB | BB | AA | *8 |
| 13 | — | — | *5 | 1.19 | 0.10 | 20.0 | — | BB | BB | BB | AA | *8 |
| 14 | — | — | *6 | 1.19 | 0.10 | 20.0 | — | BB | BB | BB | AA | *8 |
| 15 | — | — | *7 | 1.19 | 0.10 | 20.0 | — | BB | BB | BB | AA | *8 |
| 16 | A208F | 1.19 | — | — | 0.10 | 20.0 | — | AA | AA | AA | BB | *8 |
| 17 | A208N | 1.19 | — | — | 0.10 | 20.0 | — | AA | AA | AA | BB | *8 |
| 18 | A215C | 1.19 | — | — | 0.10 | 20.0 | — | AA | AA | AA | BB | *8 |
| 19 | DDP-2 | 1.19 | — | — | 0.10 | 20.0 | — | AA | AA | AA | BB | *8 |
| 20 | DDP-4 | 1.19 | — | — | 0.10 | 20.0 | — | AA | AA | AA | BB | *8 |
| 21 | A208N | 0.54 | *1 | 0.65 | 0.10 | 20.0 | — | AA | AA | BB | AA | *8 |
| 22 | A215C | 0.54 | *1 | 0.65 | 0.10 | 20.0 | — | AA | AA | BB | AA | *8 |
| 23 | DDP-2 | 0.54 | *1 | 0.65 | 0.10 | 20.0 | — | AA | AA | BB | AA | *8 |
| 24 | DDP-4 | 0.54 | *1 | 0.65 | 0.10 | 20.0 | — | AA | AA | BB | AA | *8 |

*1: Near-infrared ray absorbing composition No.
*2: Phosphoric acid ethyl ester
*3: Phosphoric acid methyl ester
*4: Phosphoric acid i-propyl ester
*5: Phosphoric acid n-butyl ester
*6: Phosphoric acid n-octyl ester
*7: Phosphoric acid n-dodecyl ester
*8: Present Invention

TABLE II

| | | | | | Formula (I) | | | | | | | |
|---|---|---|---|---|---|---|---|---|---|---|---|---|
| | Formula (1) | | Formula (2) | | Compound | Solid | | Evaluation result | | | | |
| | compound | | compound | | Added | Content | | | Transmit- | Transmit- | Transmit- | |
| | | Mole | | Mole | amount | Ratio | | Average | tance 1 | tance 2 | tance 3 | |
| *2 | Species | number | Species | number | (mass %) | (mass %) | *13 | Particlesize | (550 nm) | (750 nm) | (1000 nm) | Remarks |
| 25 | *3 1 | 0.54 | *4 | 0.65 | 0.10 | 20.0 | — | AA | AA | BB | AA | *14 |
| 26 | *3 2 | 0.54 | *4 | 0.65 | 0.10 | 20.0 | — | AA | AA | BB | AA | *14 |
| 27 | *3 3 | 0.54 | *5 | 0.65 | 0.10 | 20.0 | — | AA | AA | BB | AA | *14 |
| 28 | *3 4 | 0.54 | *6 | 0.65 | 0.10 | 20.0 | — | AA | AA | BB | AA | *14 |
| 29 | A208F | 0.54 | *7 | 0.65 | 0.10 | 20.0 | — | AA | AA | BB | AA | *14 |
| 30 | A208F | 0.54 | *8 | 0.65 | 0.10 | 20.0 | — | AA | AA | BB | AA | *14 |
| 31 | A208F | 0.54 | *9 | 0.65 | 0.10 | 20.0 | — | AA | AA | BB | AA | *14 |
| 32 | A208F | 0.54 | *5 | 0.65 | 0.10 | 20.0 | — | AA | AA | BB | AA | *14 |
| 33 | A208F | 0.54 | *6 | 0.65 | 0.10 | 20.0 | — | AA | AA | BB | AA | *14 |
| 34 | A208F | 0.54 | *10 | 0.65 | 0.10 | 20.0 | — | BB | BB | BB | AA | *14 |
| 35 | A208F | 0.54 | *11 | 0.65 | 0.10 | 20.0 | — | BB | BB | BB | AA | *14 |
| 36 | A208F | 0.54 | *4 | 0.65 | 0.10 | 20.0 | FDR004 | AA | AA | BB | AA | *14 |
| 37 | A208F | 0.54 | *4 | 0.65 | 0.10 | 20.0 | *1 | AA | AA | AA | AA | *14 |
| 38 | *3 3 | 0.54 | *5 | 0.65 | 0.10 | 20.0 | *1 | AA | AA | AA | AA | *14 |
| 39 | *3 4 | 0.54 | *6 | 0.65 | 0.10 | 20.0 | *1 | AA | AA | AA | AA | *14 |
| 40 | A208F | 0.54 | *4 | 0.65 | 15.0 | 20.0 | — | DD | DD | CC | AA | *15 |
| 41 | — | — | *12 | 1.19 | — | 20.0 | — | BB | BB | BB | DD | *15 |
| 42 | A208F | 0.54 | *4 | 0.65 | — | 20.0 | — | AA | BB | BB | DD | *15 |
| 43 | — | — | *4 | 1.19 | — | 20.0 | — | BB | BB | BB | DD | *15 |
| 44 | A208F | 1.19 | — | — | — | 20.0 | — | AA | BB | BB | DD | *15 |

*1: FDR004 + Lumogen R765
*2: Near-infrared ray absorbing composition No.
*3: Exemplary compound
*4: Phosphoric acid ethyl ester
*5: Phosphoric acid n-octyl ester
*6: Phosphoric acid n-dodecyl ester
*7: Phosphoric acid methyl ester
*8: Phosphoric acid i-propyl ester
*9: Phosphoric acid n-butyl ester
*10: Phosphoric acid stearyl ester
*11: Phosphoric acid phenyl ester
*12: Phosphoric acid 2-methacryloxyethyl ester
*13: Near-infrared Absorption modifier
*14: Present Invention
*15: Comparative Example

As is clear from the results shown in Table I and Table II, the near-infrared ray absorptive composition of the present invention has a small average particle size of copper complex particles, is excellent in spectral characteristics, has a high transmittance in the visible region (550 nm), a low transmittance in the near-infrared region (1000 nm), and an excellent near-infrared light cutting ability in comparison with Comparative Example, by adopting the constitution defined in the present invention. It was also confirmed that the near-infrared ray absorbing compositions 1 to 44 all had an average transmittance in the visible region of 70% or more.

### Example 2

### <<Preparation of Near-Infrared Ray Absorbing Film>>

To each of the near-infrared ray absorbing compositions prepared in Example 1, a polysiloxane silicone resin (KR-255, manufactured by Shin-Etsu Chemical Industry Co., Ltd.) was added and stirred to prepare a coating liquid for forming a near-infrared ray absorbing film. The prepared coating liquid was applied onto a substrate by spin coating to prepare near-infrared ray absorbing films 1 to 44.

Next, the coating film was cured by performing a predetermined heat treatment on the near-infrared ray absorbing film, and near-infrared ray cut filters 1 to 44 applicable to an image sensor for a solid-state imaging device were produced.

With respect to each of the near-infrared ray cut filters produced above, the visible light transmittance and the near-infrared light transmittance in the film state were evaluated in the same manner as in the method described in Example 1. As a result, it was confirmed that the same effect was obtained even with the film system.

### INDUSTRIAL APPLICABILITY

The near-infrared ray absorbing composition of the present invention is a near-infrared ray absorbing composition having high dispersibility and high transmittance in the visible region and excellent absorption characteristics in the near-infrared region, and the near-infrared ray absorbing film produced by this near-infrared ray absorbing composition may be suitably used for an image sensor for a solid-state imaging device applied to a video camera, a digital still camera, or a mobile phone with a camera function.

### DESCRIPTION OF SYMBOLS

1: Camera Module
2, 7: Adhesive
3: Glass substrate
4: Imaging lens
5: Lens holder
6: Light and electromagnetic shield
8: Flattening layer
9: Near-infrared ray absorbing film (Near-infrared ray cut filter)
10: Solid-state imaging device substrate
11: Solder ball
12: Circuit board
13: Imaging device section

1. A near-infrared ray absorbing composition comprising a near-infrared absorber and a solvent, wherein the near-infrared absorber contains at least one of the following component (A) and component (B); and a compound having a structure represented by Formula (I) is contained in the component (A) or component (B) in the range of 0.001 to 10% by mass based on the total mass of the near-infrared ray absorbing composition,
Component (A): a component composed of at least one of a compound having a structure represented by Formula (1) or Formula (2) with a compound having a structure represented by Formula (I) and a copper ion
Component (B): a component composed of a copper complex obtained by reaction of at least one of a compound having a structure represented by Formula (1) or Formula (2) with a compound having a structure represented by Formula (I) and a copper compound,
O═P—(OH)₃ Formula (I): 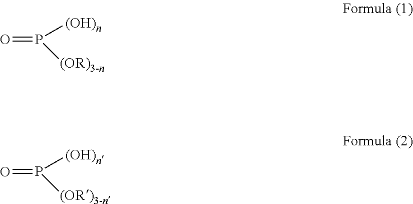
in the above Formula (1), R represents at least one group selected from the Formulas (A) to (H) and (J); n represents 1 or 2, and when n represents 1, a plurality of R may be the same or different,
in the above Formula (2), R′ represents an alkyl group, an aryl group, an aralkyl group, or an alkenyl group each having 1 to 18 carbon atoms, and the total carbon atom number is in the range of 1 to 36; n′ represents 1 or 2, and when n′ represents 1, a plurality of R′ may be the same or different, 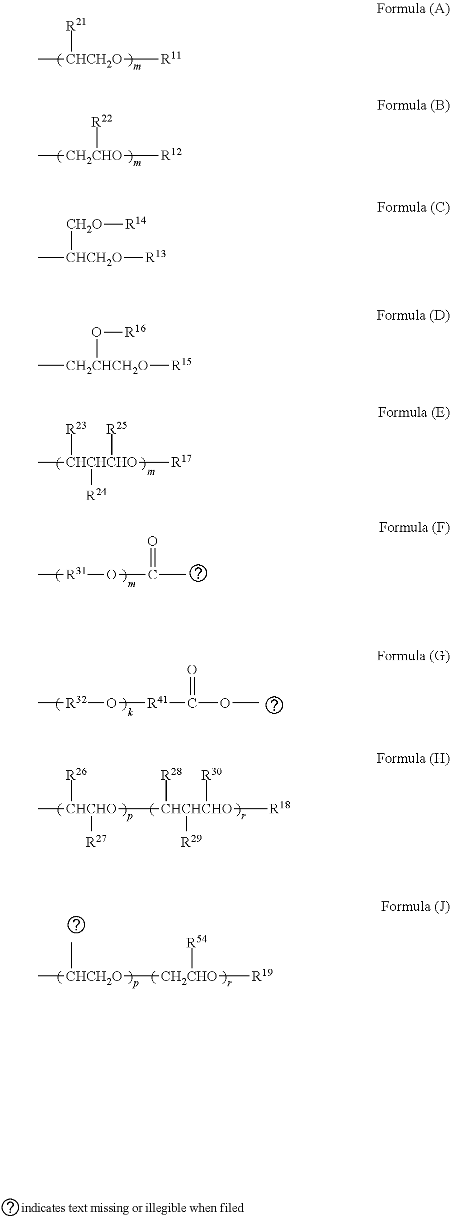
in the above Formulas (A) to (H) and (J), R¹¹ to R¹⁹ each respectively represent an alkyl group having 1 to 20 carbon atoms, an aryl group having 6 to 20 carbon atoms, or an aralkyl group having 6 to 20 carbon atoms (provided that at least one hydrogen atom bonded to a carbon atom constituting an aromatic ring may be substituted with an alkyl group having 1 to 6 carbon atoms, or a halogen); R²¹ to R³⁰ each respectively represent a hydrogen atom or an alkyl group having 1 to 4 carbon atoms; R³¹ and R³² each respectively represent an alkylene group having 1 to 6 carbon atoms; R⁴¹ represents an alkylene group having 1 to 10 carbon atoms; R⁵¹ and R⁵² each respectively represent an alkylene group having 1 to 20 carbon atoms; and R⁵³ and R⁵⁴ each respectively represent a hydrogen atom or an alkyl group having 1 to 4 carbon atoms, provided that one of R⁵³ and R⁵⁴ is always a hydrogen atom, and both of R⁵³ and R⁵⁴ are not a hydrogen atom at the same time; m represents an integer of 1 to 12, k represents an integer of 0 to 5, p represents an integer of 1 to 10, and r represents an integer of 1 to 10.

2. The near-infrared ray absorbing composition described in claim 1, wherein a solid content concentration is in the range of 5 to 50% by mass.

3. The near-infrared ray absorbing composition described in claim 1, wherein an average transmittance in a wavelength range of 450 to 550 nm is 70% or more when a transmittance at a wavelength of 850 nm is made to 1.0%.

4. The near-infrared ray absorbing composition described in claim 1, containing a near-infrared absorption modifier having an absorption maximum wavelength in a wavelength range of 650 to 1000 nm.

5. A near-infrared ray absorbing film formed with the near-infrared ray absorbing composition described in claim 1 is used.

6. An image sensor for a solid-state imaging device comprising the near-infrared ray absorbing film described in claim 5.
